(19) United States
(12) Patent Application Publication
(10) Pub. No.: US 2008/0157073 A1
(43) Pub. Date: Jul. 3, 2008

(54) Integrated Transistor Devices

(76) Inventor: Walter David Braddock, Rochester, MN (US)

Correspondence Address: NEIFELD IP LAW, PC, 4813-B EISENHOWER AVENUE, ALEXANDRIA, VA, 22304, US

(21) Appl. No.: 11/618,212

(22) Filed: Dec. 29, 2006

(51) Int. Cl. H01L 29/78; H01L 21/34

(52) U.S. Cl. 257/43; 438/104; 257/E29.255; 257/E21.46

(57) ABSTRACT

A self-aligned enhancement mode metal-oxide-compound semiconductor field effect transistor (10) includes a lower oxide layer that is a mixture of Ga₂O, Ga₂O₃, and other gallium oxide compounds (30), and a second insulating layer that is positioned immediately on top of the gallium oxygen layer together positioned on upper surface (14) of a III-V compound semiconductor wafer structure (13). Together the lower gallium oxide compound layer and the second insulating layer form a gallium oxide gate insulating structure. The gallium oxide gate insulating structure and underlying compound semiconductor gallium arsenide layer (15) meet at an atomically abrupt interface at the surface of with the compound semiconductor wafer structure (14). The initial essentially gallium oxygen layer serves to passivate and protect the underlying compound semiconductor sure from the second insulating oxide layer. A refractory mal gate electrode layer (17) is positioned on upper surface (18) of the second insulating oxide layer. The refractory metal is stable on the second insulating oxide layer at elevated temperate. Self-aligned source and drain areas, and source and drain contacts (19, 20) are positioned on the source and drain areas (21, 22) of the device. Multiple devices are then positioned in proximity and the appropriate interconnection metal layers at insulators are utilized in concert with other passive circuit elements to form a integrated circuit structure.

### CROSS-REFERENCE TO RELATED APPLICATIONS

This application claims priority under 35 USC 119(e) to provisional application serial No. 60/1201,739, filed May 4, 2000.

### STATEMENT AS TO FEDERALLY SPONSORED RESEARCH

This invention was made with the support of the United States government under US Army and Missile Command Contract Number(s) DAAH01-C-R015, DAAH01-C-R028. The United States may have certain rights in the invention.

### BACKGROUND OF THE INVENTION

1. Field of the Invention

The present invention pertains to low power and high speed integrated circuits in the compound semiconductor field utilizing field effect transistors and more specifically complementary field effect transistors used in concert including enhancement mode self-aligned metal-oxide-compound semiconductor transistors and depletion mode self-aligned metal-oxide-compound semiconductor transistors and methods of materials growth and fabrication of said structures and the ultra large scale integration of said transistors.

2. Discussion of the Background

The gallium arsenide and indium phosphide integrated circuit industry has been limited without a technology that simultaneously allows the integration of complementary field effect transistor devices and transistors with low gate leakage currents. In contrast to silicon technology that has a very mature and useful complementary metal oxide semiconductor (CMOS) technology. Field effect transistor (FETs) widely used in the III-V semiconductor industry employ metal gates and Schottky gate contacts that are have quiescent-state leakage currents exceeding many microamps. The use of metal gates in compound semiconductor technology further results in individual transistors and intergrated circuits that have excessively high power dissipation, reduced transconductance, reduced logic swing and the inability to operate on a single power supply, and generally limited performance characteristics. The high magnitude of the quiescent leakage current limits the maximum integration of GaAs devices to circuits of several hundred thousand transistors for those skilled in the art. In contrast, the simultaneous integration of many millions of transistors is possible at high integration densities using silicon CMOS technology. These ultra high integration densities and levels cannot be obtained using metal, Schottky-style gates that are not insulated in compound semiconductor FETs. Thus Si CMOS technology offers significant advantages in terms of individual gate leakage, circuit integration level and cost.

However when compared to silicon, complementary GaAs and InP circuit technology exhibits faster and more optimized speed/power performance and efficiency at a low supply voltage of 1V and below. The market acceptance of these GaAs and nip integrated circuit technologies remains low because of the lack of ability to demonstrate high integration densities with low amounts of opera power. Thus, silicon CMOS dominates the field of digital integrated circuitry and neither Gabs nor InP technologies can successfully penetrate this market.

What is needed are new and improved compound semiconductor field effect transistors (FET). What is also needed are new and improved compound semiconductor FETs using metal-oxide-semiconductor junctions (MOSFET). What is also needed are new and improved compound semiconductor MOSFETs using a self-aligned gate structure. What is also needed are new and improved self-aligned compound semiconductor MOSFETs using enhancement mode and depletion mode operation. What is also needed are new and improved self-aligned compound semiconductor MOSFETs with stable and reliable device operation. What is also needed are new and improved self-aligned compound semiconductor MOSFETs which enable optimum compound semiconductor device performance. What is also needed are new and improved self-aligned compound semiconductor MOSFETs with optimum efficiency and output power for RF and microwave applications. What is also needed are new and improved self-aligned compound semiconductor MOSFETs for use in complementary circuits and architectures. What is also needed arm new and improved self-aligned compound semiconductor MOSFETs for low power/high performance complementary circuits and architectures. What is also needed are new and improved self-aligned compound semiconductor MOSFETs which offer the design flexibility of complementary architectures. What is also needed arm new and improved self-aligned compound semiconductor MOSFETs which keep interconnection delays in ultra large scale integration under control. What is needed are new and useful complementary integrated circuits where each individual transistor has a leakage current approaching 10⁻¹² amp. What is needed is a truly useful inter circuit technology for GaAs and hip that allows for the useful and economical operation of ULSI digital intergrated circuits in compound semiconductors. What is needed are new and improved compound semiconductor MOSFET integrated circuits with very low net power dissipation. What is needed are new and improved compound semiconductor MOSFET devices with low gate leakage currents that may be integrated together to form ultra large scale integrated circuits that include millions of transistors. What is needed are new and improved complementary MOSFET devices and circuits in compound semiconductors that allow the direct use, transfer and application of silicon CMOS design that already exits in the art.

What is also needed are new and improved methods of fabrication of self-aligned compound semiconductor MOSFETs. What is also needed is new and improved methods of fabrication of self-aligned compound semiconductor MOSFETs which are compatible with established complementary GaAs heterostructure FETs technologies. What is also needed are new and improved compound semiconductor MOSFETs which are relatively easy to fabricate and use.

### SUMMARY OF THE INVENTION

### BRIEF DESCRIPTION OF THE DRAWINGS

A more complete understanding of the present invention may be derived by referring to the detailed description and claims when considered in connection with the figures, wherein like reference numbers refer to similar items throughout the figures, and:

FIG. 1 is simplified crow sectional view of a self-aligned enhancement mode compound semiconductor MOSFET in accordance with a preferred embodiment of the present invention;

FIG. 2 is a simplified flow chart illustrating a method of man of a self-aligned enhancement mode compound semiconductor MOSFET in accordance with a preferred embodiment of the present invention.

The exemplification set out herein illustrates a preferred embodiment of the invention in one form thereof, and such exemplification is not intended to be construed as limiting in any manner.

### DETAILED DESCRIPTION OF THE PREFERRED EMBODIMENTS

The present invention provides, among other things, a self-aligned enhancement mode metal-oxide-compound semiconductor FET. The FET includes a gallium oxygen insulating structure that is composed of at least two distinct layers. The first layer is most preferably more that 10 angstroms thick but less that 25 angstroms in thickness and composed substantially of gallium oxygen compounds including but not limited to stoichiometric Ga₂O₃ and Ga₂O, and possibly a lesser fraction of other gallium oxygen compounds. The upper insulating layer in the gallium oxide insulating structure is composed of an insulator that does not intermix with the underlying gallium oxygen insulating structure. This upper layer must possess excellent insulating qualities, and is most typically composed of gallium oxygen and a third rare earth element that together form a ternary insulating material. Therefore the entire gallium oxide rare earth gate insulator structure is composed of at least two layers and may contain a third intermediate graded layers that consists of a mixture of the upper insulating material and the gallium oxygen compounds that compose the initial layer. Together the initial gallium oxygen layer, any intermediate graded layer and the top insulating region form both a gallium oxide insulating structure and the gate insulator region of a metal-oxide-compound semiconductor field effect transistor. The initial substantially gallium oxygen layer forms an atomically abrupt interface with the top layer of the compound semiconductor wafer structure, and does not introduce midgap surface states into the compound semiconductor material. A refractory metal gate electrode is preferably positioned on the upper surface of the gate insulator structure layer. The refractory metal is stable on the gate insulator structure layer at elevated temperature. Self-aligned source and drain areas, and source and drain contacts are positioned on the source and drain areas. In all embodiments preferred and otherwise, the metal-oxide-compound semiconductor transistor includes multi-layer gate insulator structure including an initial gallium oxygen layer, intermediate transition layer, and upper insulating layer of 30-250 angstroms in thickness positioned on upper surface of a compound semiconductor heterostructure that form the gate insulator structure. The preferred embodiment also comprises a compound semiconductor heterostructure including a GaAs, Alₓ Ga₁₋ₓ and In_{y} Ga_{1-y}. As layers with or without n-type and/or p-type charge supplying layers which are grown on a compound semiconductor substrate, a refractory metal gate of W, WN, or WSi, self aligned donor (n-channel FET) or acceptor (p-channel FET) implants, and source and drain ohmic contacts. In another preferred embodiment, the compound semiconductor heterostructure comprises an In_{y}Ga_{1-y}As, AlₓIn₁₋ₓAs, and InP compound semiconductor heterostructure and n-type and/or p-type charge supplying layers which are grown on an InP substrate, and a refractory metal gate of W, WN, or WSi, self aligned donor (n-channel VET) or acceptor (p-channel FET) implants, and source and drain ohmic contacts.

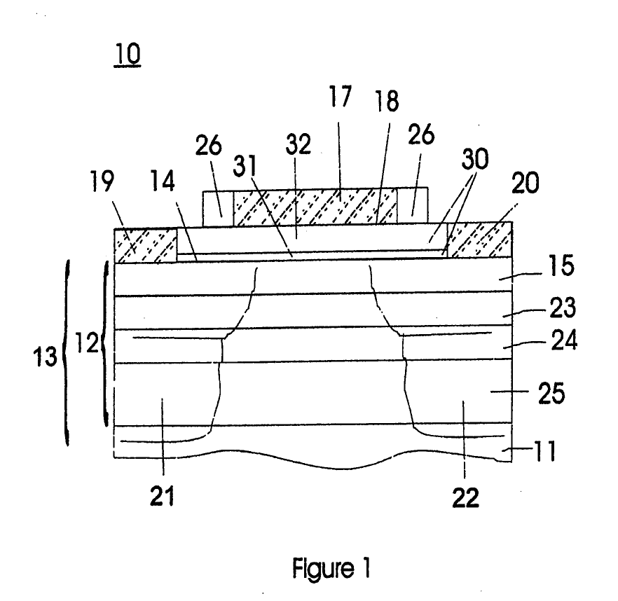

FIG. 1 is simplified cross-sectional view of a self-aligned enhancement mode compound semiconductor MOSFET in accordance with a preferred embodiment of the present invention. Device 10 includes a compound semiconductor material, such as any III-V material employed in any semiconductor device, represented herein by a III-V semiconductor substrate 11 and a compound semiconductor epitaxial layer structure 12. For the purpose of this disclosure, the substrate 11 and any epitaxial layer structure 12 formed thereon will be referred to simply as a compound semiconductor wafer structure which in FIG. 1 is designated 13. Methods of fabricating semiconductor wafer structure 13 include, but are not limited to, molecular beam epitaxy (MBE) and metal organic chemical vapor deposition (MOCVD). It will of course be understood that in some specific applications, there may be no epitaxial layers present and upper surge of top layer 15 may simply be the upper surface of substrate 11.

Device 10 further comprises a gate insulator structures (30) that includes at least two or more layers. The first layer of the gate insulator structure (31) is composed entirely of gallium oxide compounds and is directly adjacent to and deposited upon the compound semiconductor structure. The second layer of the gate insulator structure (32) is composed of a compound of gallium, oxygen, and one or more rare earth elements from the periodic table. The initial gallium oxygen layer (31) forms an atomically abrupt interface 14 with the upper surface of top layer 15, the top layer of the compound semiconductor structure. A refractory metal gate electrode 17 which is stable in the presence of top insulating material at elevated temperature is positioned on upper surface 18 of the gate insulator structure. Dielectric spacers 26 are positioned to cover the sidewalls of metal gate electrode 17. Source and drain contacts 19 and 20 are deposited on self-aligned source and drain areas 21 and 22, respectively.

In a specific embodiment, the compound semiconductor epitaxial layer structure consists of a <11 angstrom GaAs top layer (15), a <101 angstrom AlₓGa₁₋ₓAs spacer layer (23), a <251 angstrom In_{y}Ga₁₋ₓAs channel layer (24), and a GaAs buffer layer (25) grown on a GaAs substrate (11). Top GaAs layer (15) is used to form an atomically abrupt layer with the gate insulator structure with an abrupt interface with low defect density.

As a simplified example of fabricating a self-aligned enhancement mode compound semiconductor MOSFET in accordance with a preferred embodiment of the present invention, a III-V compound semiconductor wafer structure 13 with an atomically ordered and chemically clean upper surface of top layer 15 is prepared in an ultra-high vacuum semiconductor growth chamber and transferred via a ultra high vacuum transfer chamber to a second ultra high vacuum oxide and insulator deposition chamber. The initial gallium oxygen layer (31) is deposited on upper compound semiconductor surface layer 15 using thermal evaporation from a high purity Ga₂O₃ source or from crystalline gadolinium gallium garnet, Ga₃Gd₅O₁₂. This initial gallium oxygen layer is deposited while holding the substrate temperature of the compound semiconductor structure at <580° C., and most preferably at a substrate temperature <495° C. After the deposition of approximately 18 angstroms of gallium oxygen compounds in the insulator deposition chamber over a 5 to 8 minute period of time, deposition of the second insulator layer is initiated. The deposition of the second insulator layer starts by directing the flux from a low power oxygen plasma source into the ultra high vacuum system such that the oxygen plasma effluent and species are largely directed toward and impinging upon said compound semiconductor structure with initial gallium oxygen layer. The flux from the oxygen plasma source should be directed at the surface for between 2-5 seconds, subsequently followed by the co-evaporation of gallium oxygen compounds from Ga₂O₃ and a second thermal evaporation source that contains a re-earth element. The flux beams from the oxygen source, Ga₂O₃ and rare-earth evaporation source thermal evaporation sources are carefully balanced to provide a ternary insulator layer on top of the initial gallium oxygen layer on said compound semiconductor structure. As the deposition of the second ternary insulator layer is initiated, the substrate temperature is simultaneously adjusted to provide an optimized substrate temperature for the deposition of this layer. In this example the substrate temperature required to deposit the gallium+oxygen+rare earth layer is <530° C. The deposition of this second insulator layer proceeds until the total insulator thickness of 200-250 angstroms is achieved. Shutters and valves are utilized to stop the deposition of the ternary gallium+oxygen+more earth layer upon the deposition of the required thickness of the insulator layer. The substrate temperature is cooled in-vacuum to approximately 200° C. and the deposition of a refractory metal which is stable and does not interfuse with on the top layer of the gate insulator structure at elevated temperature such as WSi or WN is deposited on upper surface 18 of oxide layer 32 and subsequently patterned using standard lithography. The refractory metal layer is etched until oxide layer 31 is exposed using a refractory metal etching technique such as a fluorine based dry etching process. The refractory metal etching procedure does not etch the oxide layer 31, thus, oxide layer 31 functions as an etch stop layer such that upper surface of top layer 15 remains protected by oxide layer 31. All processing steps are performed using low damage plasma processing. Self-aligned source and drain areas 21 and 22, respectively are realized by ion implantation of Si (n-channel device) and Be/F or C/F (p-channel device) using the refractory metal gate electrode 17 and the dielectric spacers 26 as implantation masks. Such ion implantation schemes are compatible with standard processing of complementary compound semiconductor heterostructure FET technologies and are well known to those skilled in the art. The implants are activated at 700-900° C. using rapid thermal annealing in an ultra high vacuum environment such that degradation of the interface 16 established between top layer 15 and oxide layer 31 is completely excluded. Finally, ohmic source and drain contacts 19 and 20 are deposited on the self-aligned source and drain areas 21 and 22, respectively. The devices may then be interconnected using the standard methods to those skilled in the art of integrated microelectronics and integrated circuit manufacture.

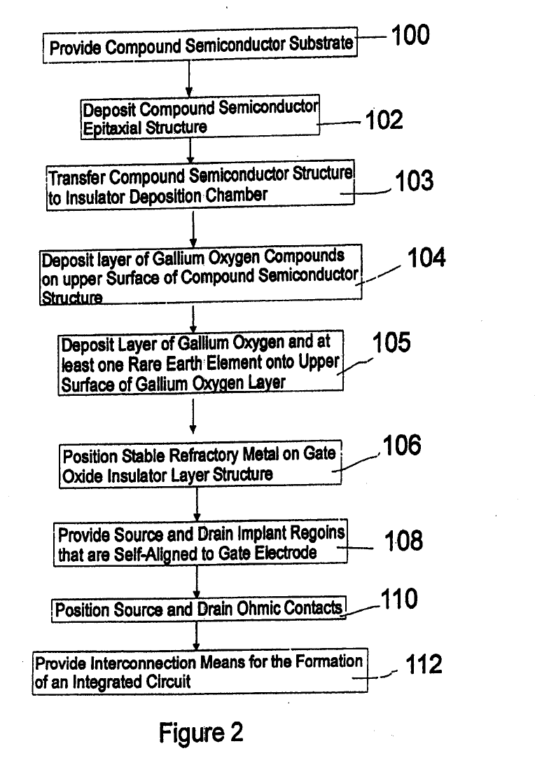

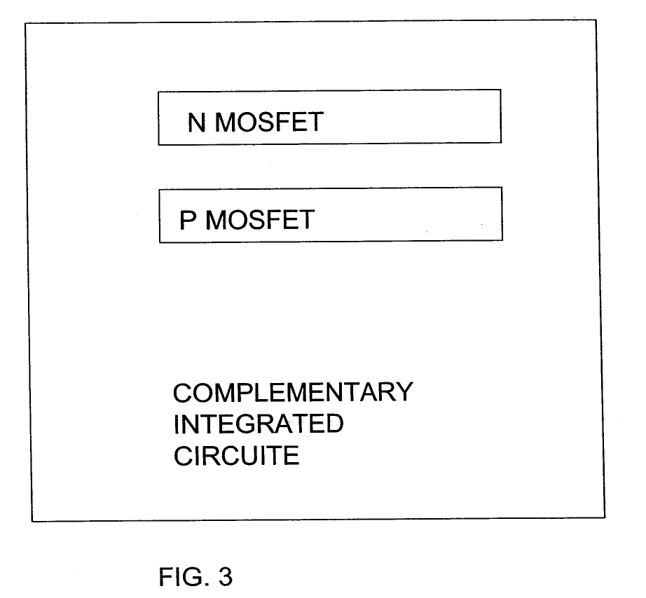

FIG. 2 is a simplified flow chart illustrating a method of manufacturing a self-aligned enhancement mode compound semiconductor MOSFET in accordance with a preferred embodiment of the present invention. In step 102, a compound semiconductor wafer structure is produced using standard epitaxial growth methods in the art. In step 103, a layer consisting of gallium oxygen compounds including but not limited to Ga₂O₃ and Ga₂O is deposited on upper surface of said compound semiconductor wafer structure. In step 104, an insulating layer of gallium oxygen and one or more rare earth elements is deposited on the upper surface of the initial gallium oxygen compound layer. The gallium oxide gate insulator structure is formed in steps 104 and 105. In step 106, a stable refractory gate metal is positioned on upper surface of said gate insulator structure. In step 108, source and drain ion implants are provided self-aligned to the gate electrode. In step 110, source and drain ohmic contacts are positioned on ion implanted source and drain areas.

In a preferred embodiment, step 100 provides a compound semiconductor substrate such as GaAs or InP. Step 102 includes the preparation and epitaxial growth of an atomically ordered and chemically clean upper surface of the compound semiconductor wafer structure. Step 103 preferably comprises thermal evaporation from a purified and crystalline gadolinium gallium garnet or Ga₂O₃ source on an atomically ordered and chemically clean upper surface of the compound semiconductor wafer structure. Step 104 comprises the formation of a gallium+oxygen+rare earth elemental insulating layer formed through the simultaneous vacuum evaporation of gallium oxygen species and at least one rare earth element such as Gadolinium with the simultaneous oxidation using the effluent of an oxygen gas plasma source directed in simultaneous combination with other thermal evaporation sources toward substrate 100. The initial gallium oxygen compound layer of the gate insulator structure preferably functions as an etch stop layer such that the upper surface of the compound semiconductor wafer structure remains protected by the gate oxide during and after gate metal etching. The refractory gate metal desirably does not react with or diffuse into the gate oxide layer during high temperature annealing of the self-aligned source and drain ion implants. The quality of the interface formed by the gate oxide layer and the upper surface of the compound semiconductor structure is desirably preserved during high temperature annealing of the self-aligned source and drain ion implants. The self-aligned source and drain implants are desirably annealed at approximately 700° C. in an ultra high vacuum environment. The self-aligned source and drain implants are desirably realized by positioning dielectric spacers on the sidewalls of the refractory gate metal.

Thus, new and improved compound semiconductor devices and methods of fabrication are disclosed. The new and improved self-aligned enhancement mode metal-oxide-compound semiconductor heterostructure field effect transistors enable stable and reliable device operation, provide optimum compound semiconductor device performance for low power/high performance complementary circuits and architectures, keep interconnection delay in ULSI under control, and provide optimum efficiency and output power for RF and microwave applications as well as for digital integrated circuits that require very high integration densities.

These improvements essentially solve or overcome the problems of the prior art, such as high gate leakage in compound semiconductor FET devices, low integration densities, dc electrical instability, and electrical hysterisis, and therefore provide a highly useful invention. While we have shown and described specific embodiments of the present invention, further modifications and improvements will occur to those skilled in the art. We desire it to be understood, therefore, that this invention is not limited to the particular forms shown and we intend in the appended claims to cover all modifications that do not depart from the spirit and scope of this invention.

1-37. (canceled)

38. An metal-oxide-compound semiconductor field effect transistor structure, comprising:
a compound semiconductor wafer structure having an upper surface;
a gate insulator structure comprising a first layer and a second layer, said gate insulator on said upper surface;
a gate electrode positioned on said gate insulator structure;
wherein said first layer substantially comprises compounds of gallium and oxygen;
wherein said second layer has a composition different than said first layer and comprising a substantial amount of oxygen; and
wherein said first layer comprises at least one of Ga20 and Ga2O3.

39. The structure of claim 38 wherein said first layer substantially comprising compounds of gallium and oxygen comprises Ga20.

40. The structure of claim 38 wherein said first layer substantially comprising compounds of gallium and oxygen comprises Ga203.

41. A method of making a metal-oxide-compound semiconductor field effect transistor structure, said method comprising:
providing a compound semiconductor wafer structure having an upper surface;
providing a gate insulator structure comprising a first layer and a second layer, said gate insulator on said upper surface;
providing a gate electrode positioned on said gate insulator structure;
wherein said first layer substantially comprises compounds of gallium and oxygen;
wherein said second layer has a composition different than said first layer and comprising a substantial amount of oxygen;
wherein said first layer comprises at least one of Ga20 and Ga2O3.

42. The method of claim 41 wherein said first layer substantially comprises Ga20.

43. The method of claim 41 wherein said first layer substantially comprises Ga203.

44. A method of using a metal-oxide-compound semiconductor field effect transistor structure, said metal-oxide-compound semiconductor field effect transistor structure comprising a compound semiconductor wafer structure having an upper surface; a gate insulator structure comprising a first layer and a second layer, said gate insulator on said upper surface; a gate electrode positioned on said gate insulator structure; wherein said first layer substantially comprises compounds of gallium and oxygen; wherein said second layer has a composition different than said first layer and comprising a substantial amount of oxygen; wherein said first layer substantially comprises at least one of Ga20 and Ga2O3; and wherein said method comprises applying a voltage to said gate insulator structure.

45. The method of claim 44 wherein said first layer substantially comprises Ga20.

46. The method of claim 44 wherein said first layer substantially comprises Ga203.

47. A method of making a metal-oxide-compound semiconductor field effect transistor structure, said method comprising:
providing a compound semiconductor wafer structure having an upper surface;
providing a gate insulator structure comprising a first layer and a second layer, said gate insulator on said upper surface;
providing a gate electrode positioned on said gate insulator structure;
wherein said first layer substantially comprises compounds of gallium and oxygen;
wherein said second layer has a composition different than said first layer and comprising a substantial amount of oxygen;
wherein said providing said gate insulator structure comprises evaporating from a source comprising Ga.

48. The method of claim 47 wherein said providing a gate insulator structure comprising depositing said first layer while said compound semiconductor wafer structure is at a temperature below 580 degrees Centigrade.

49. The method of claim 47 wherein said providing said gate insulator structure comprises depositing said first layer while said compound semiconductor wafer structure is at a temperature below 495 degrees Centigrade.

50. The method of claim 47 wherein said providing said gate insulator structure comprises depositing said first layer for at least five minutes.

51. The method of claim 47 wherein said first layer has a thickness of less than 25 angstroms.

52. The method of claim 47 wherein said providing said gate insulator structure comprises evaporating from a source containing Oxygen.

53. The method of claim 47 wherein said providing said gate insulator structure comprises depositing said second layer while evaporating a source comprising a rare earth element.

54. The method of claim 53 further comprising depositing at least part of said second layer comprises while said compound semiconductor wafer structure is at a temperature below 530 degrees Centigrade.

55. The method of claim 47 wherein said second layer is at least 200 angstroms thick.

56. The method of claim 47 wherein said providing a gate electrode comprises depositing on said semiconductor wafer structure a refractory metal.

57. The method of claim 56 wherein said refractory metal comprises W.
